(19) United States
(12) Patent Application Publication
(10) Pub. No.: US 2010/0315791 A1
(43) Pub. Date: Dec. 16, 2010

(54) Printed Wiring Board and Electronic Apparatus

(76) Inventor: Hidetoshi Hatakeyama, Tokyo (JP)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/758,661

(22) Filed: Apr. 12, 2010

(30) Foreign Application Priority Data
Jun. 10, 2009 (JP) 2009-139288

(51) Int. Cl. H05K 1/18; H05K 5/00

(52) U.S. Cl. 361/752; 361/748

(57) ABSTRACT

According to an aspect of the present invention, there is provided a printed wiring board having a first surface and a second surface provided on a side opposite to the first surface, the printed wiring board including: a product portion on which electronic components are mounted; an end portion provided to have a gap with respect to the product portion; and a connection portion which connects the product portion and the end portion to each other; a first coating composition applied on the first surface of the product portion; and a second coating composition applied on the first surface of the end portion and the first surface of the connection portion so as to be separated from the first coating composition.

### CROSS-REFERENCE TO RELATED APPLICATIONS

This application is based upon and claims the benefit of priority from Japanese Patent Application No. 2009-139288, filed on Jun. 10, 2009, the entire contents of which are incorporated herein by reference.

### BACKGROUND

1. Field

An aspect of the present invention relates to a printed wiring board and an electronic apparatus.

2. Description of the Related Art

A printed circuit board (PCB) including a printed wiring board (PWB) and components mounted thereon to be used in an electronic apparatus such as a personal computer is shaped variously in accordance with each product. In a mounting line, multi-plane design in which pieces of single planes as PWB products and end materials (discard materials) are combined is generally performed.

In the multi-plane design, a single plane as a product portion and an end material is connected at given points, and the single plane is cut from the end material by routing.

The multi-plane design is performed by manual design in consideration of PCB work size allowed to be put in the mounting line, product outer shape, component direction, pop-out component, mounting prevention area, etc. in order to achieve economical optimum multi-plane cutting.

As a design technique in this type printed wiring board, in a printed wiring board, a V-cut notch portion for recognizing the presence/absence of V-cutting and the position of machining based on the shape is provided in an end portion of a discard board portion so as to be located on the outside of a V-cut recognition pattern, for example, as described in JP-2003-188482-A.

In JP-2003-188482-A, a recognition pattern is partially provided in a connection region between the product portion and the end material portion, it is however necessary to provide a conductive pattern for electrically inspecting whether or not cutting is completed normally in a position distant from the recognition pattern.

### BRIEF DESCRIPTION OF THE DRAWINGS

A general architecture that implements the various feature of the present invention will now be described with reference to the drawings. The drawings and the associated descriptions are provided to illustrate embodiments of the present invention and not to limit the scope of the present invention.

FIG. 1 illustrates the external appearance of an electronic apparatus according to a first embodiment.

FIG. 2 illustrates a printed wiring board according to this embodiment before routing.

FIG. 3 exemplarily illustrates the periphery of a connection portion of the printed wiring board.

FIG. 4 illustrates a printed wiring board according to a second embodiment.

FIG. 5 illustrates a first modification of the printed wiring board according to the second embodiment.

FIG. 6 illustrates a second modification of the printed wiring board according to the second embodiment.

FIG. 7 illustrates a printed wiring board according to a third embodiment.

FIG. 8 illustrates a first modification of the printed wiring board according to the third embodiment.

FIG. 9 illustrates a second modification of the printed wiring board according to the third embodiment.

FIG. 10 illustrates a third modification of the printed wiring board according to the third embodiment.

### DETAILED DESCRIPTION

Various embodiments according to the present invention will be described hereinafter with reference to the accompanying drawings. In general, according to one embodiment of the present invention, there is provided a printed wiring board having a first surface and a second surface provided on a side opposite to the first surface, the printed wiring board including: a product portion on which electronic components are mounted; an end portion provided to have a gap with respect to the product portion; and a connection portion which connects the product portion and the end portion to each other; a first coating composition applied on the first surface of the product portion; and a second coating composition applied on the first surface of the end portion and the first surface of the connection portion so as to be separated from the first coating composition.

Embodiments of the invention will be described below with reference to the drawings.

(Configuration of Electronic Apparatus)

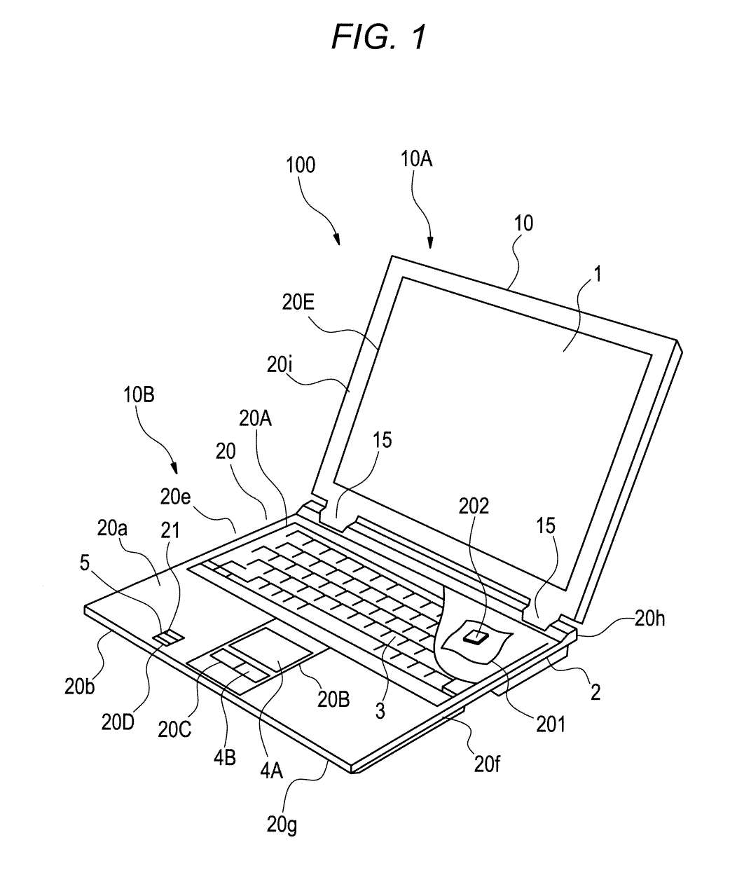

FIG. 1 illustrates the external appearance of an electronic apparatus according to a first embodiment. In FIG. 1, a notebook type personal computer is exemplified as the electronic apparatus.

The personal computer 100 (electronic apparatus) according to this embodiment includes a display portion 10A and a body portion 10B. The display portion 10A and the body portion 10B are connected to each other by hinge portions 15 so that the display portion 10A can be opened and closed with respect to the body portion 10B. The body portion 10B has a lower housing 20. A body function portion 2 which includes a printed wiring board 201 provided with electronic components such as a CPU (Central Processing Unit), a memory, etc. mounted thereon and which processes information is housed in the lower housing 20 (housing).

The lower housing 20 has a top surface 20a, a bottom surface 20b, a left side surface 20e, a right side surface 20f, a front surface 20g, and a back surface 20h. A character input portion 3, a track pad 4A, an enter switch 4B and a fingerprint reading portion 5 are housed in the lower housing 20. For example, the character input portion 3 is a keyboard for inputting characters and commands. The track pad 4A serves as a pointing device. The enter switch 4B is used for inputting select/decide commands. For example, the fingerprint reading portion 5 is used for authentication of a user. The top surface 20a has opening portions 20A to 20D. A depression portion 21 is formed in the vicinity of the opening portion 20D in the top surface 20a. The character input portion 3 is exposed from the opening portion 20A. The track pad 4A is exposed from the opening portion 20B. The enter switch 4B is exposed from the opening portion 20C. The fingerprint reading portion 5 is exposed from the opening portion 20D.

The display portion 10A has an upper housing 10. An image display portion 1 including a liquid crystal display panel, etc. for displaying characters, images, etc. is housed in the upper housing 10. The upper housing 10 has a front surface 20i. An opening portion 20E is formed in the front surface 20i. The image display portion 1 is exposed from the opening portion 20E.

(Configuration of Printed Wiring Board)

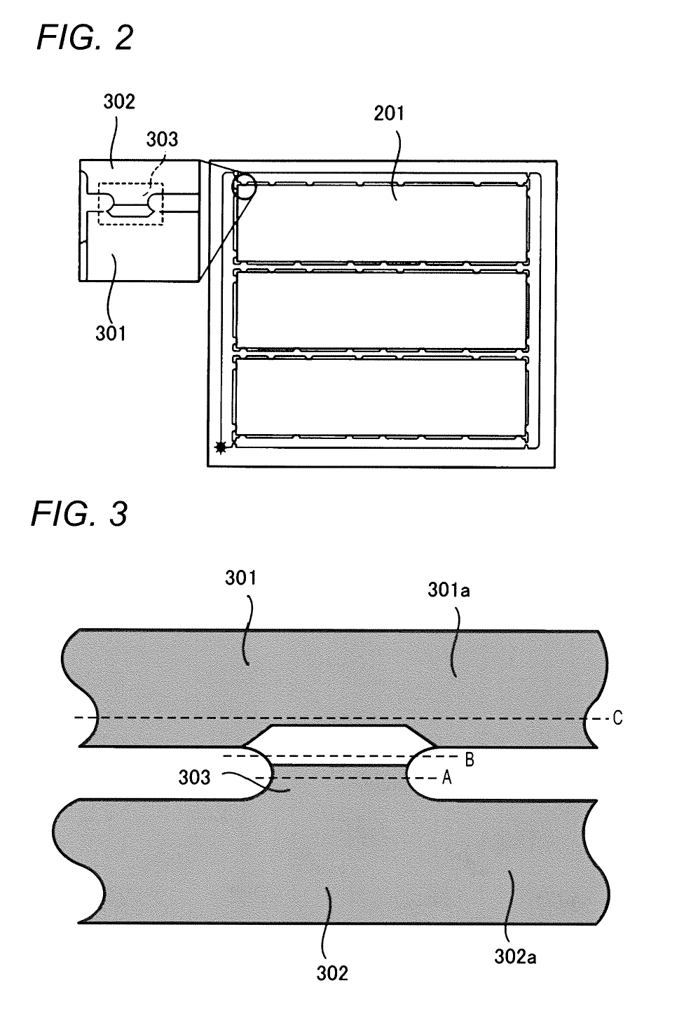

The configuration of the printed wiring board 201 to be housed in the personal computer 100 according to this embodiment will be described next with reference to FIGS. 2 and 3. FIG. 2 illustrates the printed wiring board 201, on which an electronic component 202 is mounted, before routing. FIG. 3 exemplarily illustrates the vicinity of a connection portion of the printed wiring board 201.

As shown in FIGS. 2 and 3, the printed wiring board 201 has a product portion 301 (product portion), a discard material 302 (end portion), and a connection portion 303 (connection portion). Electronic components are mounted on the product portion 301. The discard material 302 is provided around the product portion 301 through a gap. The connection portion 303 connects the product portion 301 and the discard material 302 to each other.

As shown in FIG. 3, in the printed wiring board 201 according to this embodiment, resists 301a and 302a (first and second coating compositions) are applied on the product portion 301 and the discard material 302 respectively. The resist 301a is applied on the product portion 301 around the connection portion 303. In this exemplarily embodiment, the resist 301a is applied to avoid a connection region between the product portion 301 and the connection portion 303, that is, a region not being coated with the resist 301a is provided to enters into a side of the product portion 301 from a side of the connection portion 303.

The resist 302a is applied on a surface of the discard material 302 and a surface of the connection portion 303 so that the resist 302a is separated from the resist 301a applied on the product portion 301. In this exemplarily embodiment, the resist 302a is applied to avoid a connection region between the product portion 301 and the connection portion 303, that is, the resist 302a is applied while separated from the product portion 301.

In the printed wiring board 201 according to this embodiment, after an electronic component has been mounted in the condition that the product portion 301 and the discard material 302 are connected to each other by the connection portion 303, the connection portion 303 is cut by a router cutting technique to separate the product portion 301 from the discard material 302.

As shown in FIGS. 2 and 3, there is provided a region coated with neither the resists 301a nor 302a, that is, a region in which a surface of the printed wiring board 201 is exposed along the path of a router cutting to be executed (router cut end). In the printed wiring board 201 according to this embodiment, after router cutting, whether cutting is completed normally or not can be determined/confirmed by eye observation without by providing any conductive pattern for an electrical inspection. Accordingly, in a router cutting process, production cost is reduced and working efficiency is enhanced.

As shown in FIG. 3, for example, when the router cut end after the router cutting is in a state of a router cut end A, an operating person can make a determination that cutting is not completed normally because the resist 302a remains.

When the router cut end after router cutting is in a state of a router cut end B, the operating person can make a determination that cutting is completed normally because no resist 302a remains but the region in which the surface of the printed wiring board 201 is exposed remains. When the router cut end after router cutting is in a state of a router cut end C, the operating person can make a determination that cutting is not completed normally because the region in which the surface of the printed wiring board 201 is exposed does not remain.

As described above, in the printed wiring board 201 according to this embodiment, whether cutting is completed normally or not can be determined by eye observation of the resists 301a and 302a and the region coated with neither the resists 301a nor 302a around the connection portion 303 after router cutting.

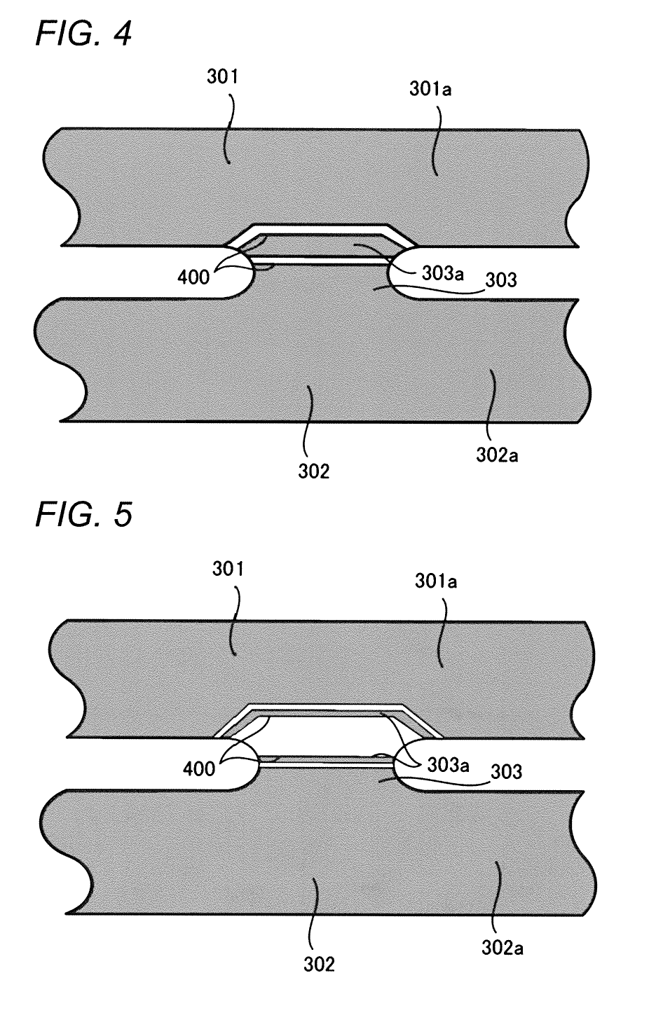

A second embodiment will be described next with reference to FIGS. 4 to 6. FIG. 4 illustrates a printed wiring board 201 according to the second embodiment. Incidentally, constituent parts having functions identical or similar to those according to the first embodiment are referred to by the same numerals and description thereof will be omitted. The point of difference of the second embodiment from the first embodiment is the shape of application of resists on the printed wiring board 201. The personal computer 100 according to the second embodiment has substantially the same external appearance as that shown in FIG. 1.

The printed wiring board 201 is to be housed in a housing of the personal computer 100. In the printed wiring board 201 according to the second embodiment, a resist 303a is provided on a region where, in the first embodiment, neither the resists 301a nor 302a are coated and the surface of the printed wiring board 201 is exposed.

As shown in FIG. 4, the resist 303a is applied between the resists 301a and 302a each through a gap. Specifically, to be along the path of a router cutting, a groove-like guide 400 is formed between the resists 303a and 301a and between the resists 303a and 302a.

According to this configuration, the same effect as in the printed wiring board 201 according to the first embodiment can be obtained.

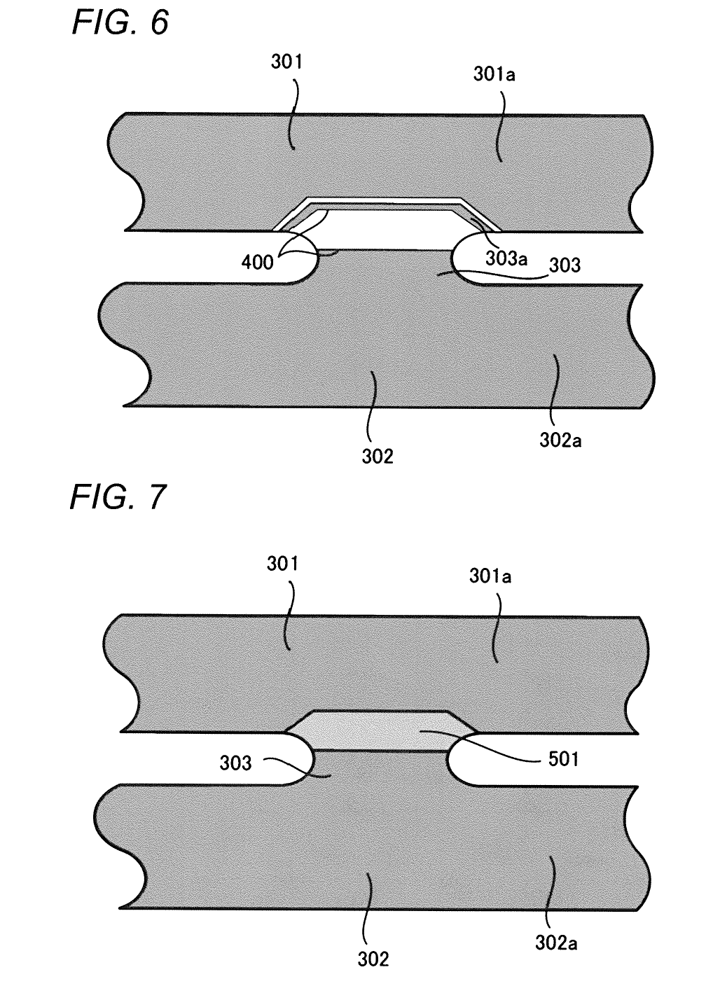

Description will be made to modifications of the second embodiment with reference to FIGS. 5 and 6. FIG. 5 illustrates a first modification of the second embodiment, in which the guide 400 includes groove-like patterns formed between the resists 303a and 301a and between the resists 303a and 302a and a linear pattern in the resist 303a. FIG. 6 illustrates a second modification of the second embodiment, in which the guide 400 is provided only on the product portion 301 side. In FIG. 6, the guide 400 includes a groove-like pattern formed between the resists 303a and 301a and a linear pattern of the resist 303a. In each modification shown in FIGS. 5 and 6, a region in which the surface of the printed wiring board 201 is exposed is further provided between the product portion 301 and the discard material 302, thereby emphasizing the guide 400 more to make visual inspection easy.

A third embodiment will be described next with reference to FIGS. 7 to 10. FIG. 7 illustrates a printed wiring board 201 according to the third embodiment. Incidentally, constituent parts having functions identical or similar to those according to the first embodiment are referred to by the same numerals and description thereof will be omitted. The point of difference of the third embodiment from the first embodiment is the shape of application of coating compositions on the printed wiring board 201. The personal computer 100 according to the third embodiment has substantially the same external appearance as that shown in FIG. 1.

The printed wiring board 201 is housed in a housing of the personal computer 100. In the printed wiring board 201 according to the third embodiment, the resist 301a in the first embodiment is applied on the whole surface of the printed wiring board 201, that is, on the product portion 301, the end material 302 and the connection portion 303. A silk print 501 as a mark is applied on a position corresponding to the region where, in the first embodiment, the surface of the printed wiring board 201 is exposed, so that the silk print 501 is provided along the path of a router cutting. The resist 302a is formed from the resist 301a by being separated therefrom through an application of the silk print 501.

According to this configuration, the same effect as in the printed wiring board 201 according to the first embodiment can be obtained.

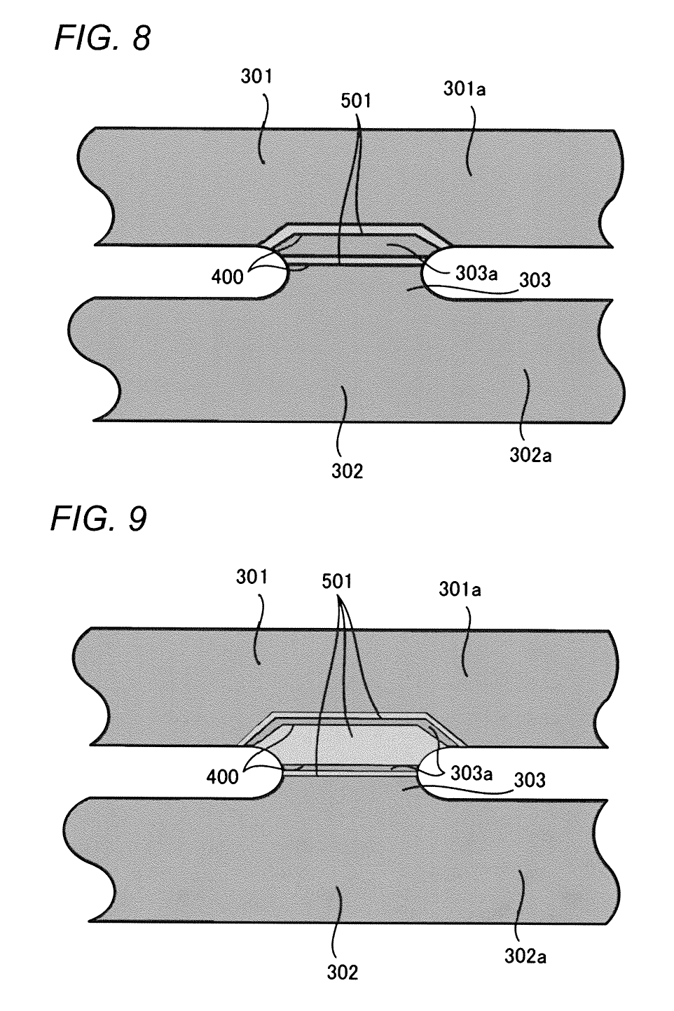

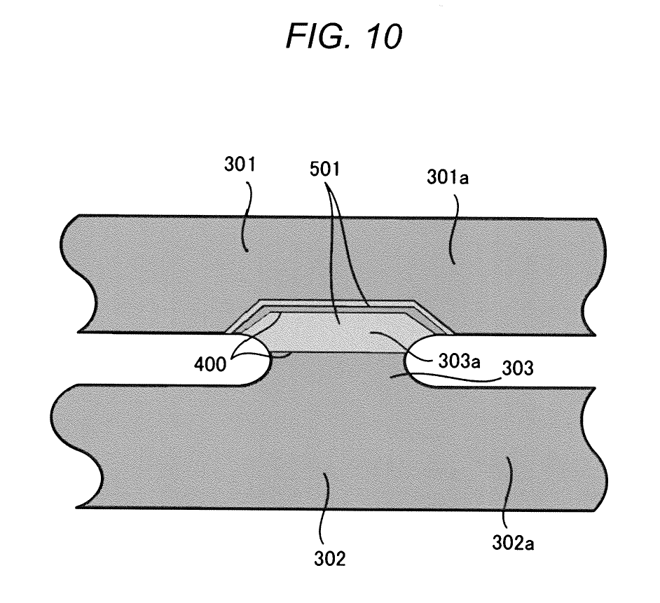

Modifications of the third embodiment will be described with reference to FIGS. 8 and 10. FIG. 8 illustrates a first modification of the third embodiment, in which the guide 400 includes linear patterns of the silk print 501 provided on the product portion 301 side and the end material 302 side respectively. FIG. 9 illustrates a second modification of the third embodiment, in which the guide 400 includes double-line patterns of the silk print 501 provided on the product portion 301 side and the end material 302 side respectively. FIG. 10 illustrates a third modification of the third embodiment, in which the guide 400 includes a linear pattern of the silk print 501 provided only on the product portion 301 side.

In each modification shown in FIGS. 8 to 10, the silk print 501 is applied so as to form the guide 400 surrounding the path of the router. Accordingly, the guide 400 is emphasized more to make visual inspection easy.

Although the personal computers (portable computers) 100 according to the first to third embodiments and the modifications of these embodiments have been described, the invention is not limited thereto. Constituent members of the first to third embodiments and the modifications of these embodiments can be combined suitably in practical use.

The electronic apparatus to which the invention can be applied is not limited to a personal computer. For example, the invention can be applied to various electronic apparatuses such as a digital camera, a video camera, a personal digital assistant, etc.

According to an aspect of the present invention, efficiency concerned with routing work is improved.

What is claimed is:

1. A printed wiring board having a first surface and a second surface provided on a side opposite to the first surface, the printed wiring board comprising:
a product portion on which electronic components are mounted;
an end portion provided to have a gap with respect to the product portion; and
a connection portion which connects the product portion and the end portion to each other;
a first coating composition applied on the first surface of the product portion; and
a second coating composition applied on the first surface of the end portion and the first surface of the connection portion so as to be separated from the first coating composition.

2. The printed wiring board of claim 1,
wherein the first coating composition is applied around the connection portion through a gap.

3. The printed wiring board of claim 2,
wherein a first guide is provided in an edge portion of the first coating composition so as to correspond to a path of a router cutting.

4. The printed wiring board of claim 3,
wherein a second guide is provided in an edge portion of the second coating composition so as to correspond to the path of the router cutting.

5. The printed wiring board of claim 4, further comprising:
a third coating composition applied on the first surface between the first coating composition and the second coating composition,
wherein the third coating composition is provided to have a gap with the first coating composition, thereby forming the first guide on the first surface of the product portion, and
wherein the third coating composition is provided to have a gap with the second coating composition, thereby forming the second guide on the first surface of the connection portion.

6. The printed wiring board of claim 3, further comprising:
a fourth coating composition which is applied on an edge portion of the first coating composition, thereby forming the first guide.

7. A printed wiring board having a first surface and a second surface provided on a side opposite to the first surface, the printed wiring board comprising:
a product portion on which electronic components are mounted;
an end portion provided to have a gap with respect to the product portion; and
a connection portion which connects the product portion and the end portion to each other;
a coating composition applied on the first surface of the product portion and the first surface of the end portion so as to stride over the connection portion; and
a guide coating composition applied on the first surface of the product portion and the first surface of the connection portion so as to correspond to a path of a router cutting.

8. An electronic apparatus comprising:
a housing; and
the printed wiring board of claim 1 hosed in the housing.

9. The electronic apparatus of claim 8,
wherein the first coating composition is applied around the connection portion through a gap.

10. The electronic apparatus of claim 9,
wherein a first guide is provided in an edge portion of the first coating composition so as to correspond to a path of a router cutting.
